(19) United States
(12) Patent Application Publication
(10) Pub. No.: US 2023/0389219 A1
(43) Pub. Date: Nov. 30, 2023

(54) Methods, Apparatus And Computer Program Products For Providing A Data Center Cabling Design Utilizing A Centralized Hub

(71) Applicant: META PLATFORMS, INC., Menlo Park, CA (US)

(72) Inventors: Blanche Sydney Christina Chisholm, Arlington, VA (US); Shawn Blanchard, Marana, AZ (US); Ashkon Baharlou, Brooklyn, NY (US); Shawn Loren Blosser, Martinez, CA (US); Victor Mah, Honolulu, HI (US)

(21) Appl. No.: 18/061,623

(22) Filed: Dec. 5, 2022

Related U.S. Application Data
(60) Provisional application No. 63/345,533, filed on May 25, 2022.

(51) Int. Cl. H05K 7/18; G02B 6/44; G06F 13/40

(52) U.S. Cl. CPC H05K 7/18; G02B 6/4446; G06F 13/4068

(57) ABSTRACT

A system for reducing onsite data center patching by implementing pre-patched racks is disclosed. The system may reduce onsite patching by having racks with pre-integrated fiber patching and associated network equipment and one or more reconfigurable fiber shuffle boxes such as optical box modules. The racks of the system may connect to an optical box module(s), which may be a central hub, that handles all the fiber shuffling and/or patching logic of the racks. In an instance in which additional racks may be needed, these additional racks may be plugged into the optical box module, which may port/connect applicable fiber strands to the additional racks, either using active or passive mechanisms.

### CROSS-REFERENCE TO RELATED APPLICATIONS

This application claims the benefit of U.S. Provisional Application No. 63/345,533 filed May 25, 2022, entitled “Methods, Apparatuses And Computer Program Products For Providing A Data Center Cabling Design Utilizing A Centralized Hub,” the entire content of which is incorporated herein by reference.

### TECHNOLOGICAL FIELD

Exemplary embodiments of this disclosure relate generally to methods, apparatuses and computer program products for facilitating a data center cabling design based in part on utilizing a centralized hub.

### BACKGROUND

The infrastructure of many existing data centers typically requires many total labor hours (e.g., over 100,000 hours) per data center site to install inside plant (ISP) cabling/infrastructure and outside plant (OSP) pigtail cabling. This inordinate amount of total labor hours to handle cabling install may reduce schedule flexibility and decrease a data center's ability to add capacity in a scalable manner.

In view of the foregoing drawbacks, it may be beneficial to provide an efficient and reliable mechanism to reduce onsite data center cabling requirements and minimize total labor hours pertaining to cabling installs associated with a data center.

### BRIEF SUMMARY

The exemplary embodiments may relate to a mechanism for reducing onsite data center cable patching by having data racks with pre-integrated fiber patching and associated network equipment, and/or one or more reconfigurable optical shuffle boxes.

The data racks (also referred to herein as racks) associated with a data center may connect to a centralized hub such as, for example, the reconfigurable optical shuffle boxes (also referred to herein as an optical box module). The centralized hub may handle all, or a portion of, the fiber/cable shuffling for the data racks associated with a data center. In an instance in which additional data racks may be required for the data center, these additional data racks may be plugged into the centralized hub, which may port/connect applicable strands of fiber (e.g., cable) as needed, either using active and/or passive mechanisms.

By implementing pre-patched racks that connect to a centralized hub, the exemplary embodiments may reduce onsite data center labor associated with cable patching.

For example, the centralized hub may have a cabling design in a first configuration (also referred to herein as Configuration 1) and a second configuration (also referred to herein as Configuration 2). The Configuration 1 and Configuration 2 may enable reduction of the labor hours associated with cable patching of an onsite data center to approximately 44,000 hours and approximately 12,000 hours respectively by aggregating patching into centrally defined points of the centralized hub. This may be a significant improvement since as described above the infrastructure of many existing/standard data centers may require over 100,000 total labor hours associated with cable patching.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

The summary, as well as the following detailed description, is further understood when read in conjunction with the appended drawings. For the purpose of illustrating the disclosed subject matter, there are shown in the drawings exemplary embodiments of the disclosed subject matter; however, the disclosed subject matter is not limited to the specific methods, compositions, and devices disclosed. In addition, the drawings are not necessarily drawn to scale. In the drawings:

FIG. 1 is a diagram of an exemplary network environment in accordance with an exemplary embodiment.

FIG. 2 is a diagram of an exemplary centralized hub in accordance with an exemplary embodiment.

FIG. 3 is a diagram of an exemplary data rack in accordance with an exemplary embodiment.

FIG. 4 is a diagram illustrating an optical box module having internal ports connected to data racks in accordance with an exemplary embodiment.

FIG. 5 is a diagram illustrating multiple optical box modules configured to connect to dedicated racks in accordance with an exemplary embodiment.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein. Like reference numerals refer to like elements throughout. As used herein, the terms “data,” “content,” “information” and similar terms may be used interchangeably to refer to data capable of being transmitted, received and/or stored in accordance with embodiments of the invention. Moreover, the term “exemplary”, as used herein, is not provided to convey any qualitative assessment, but instead merely to convey an illustration of an example. Thus, use of any such terms should not be taken to limit the spirit and scope of embodiments of the invention.

As defined herein a “computer-readable storage medium,” which refers to a non-transitory, physical or tangible storage medium (e.g., volatile or non-volatile memory device), may be differentiated from a “computer-readable transmission medium,” which refers to an electromagnetic signal.

As referred to herein, cable patching and/or a cable patch may relate to an electrical and/or optical cable/fiber utilized to connect an electronic device and/or optical device to one or more other devices to route one or more signals.

As referred to herein, a rack(s) may be any open 2-post, 4-post or enclosed cabinet that includes active rack mounted electronics, copper and/or fiber optics.

It is to be understood that the methods and systems described herein are not limited to specific methods, specific components, or to particular implementations. It is also to be understood that the terminology used herein is for the purpose of describing particular embodiments only and is not intended to be limiting.

### Exemplary System Architecture

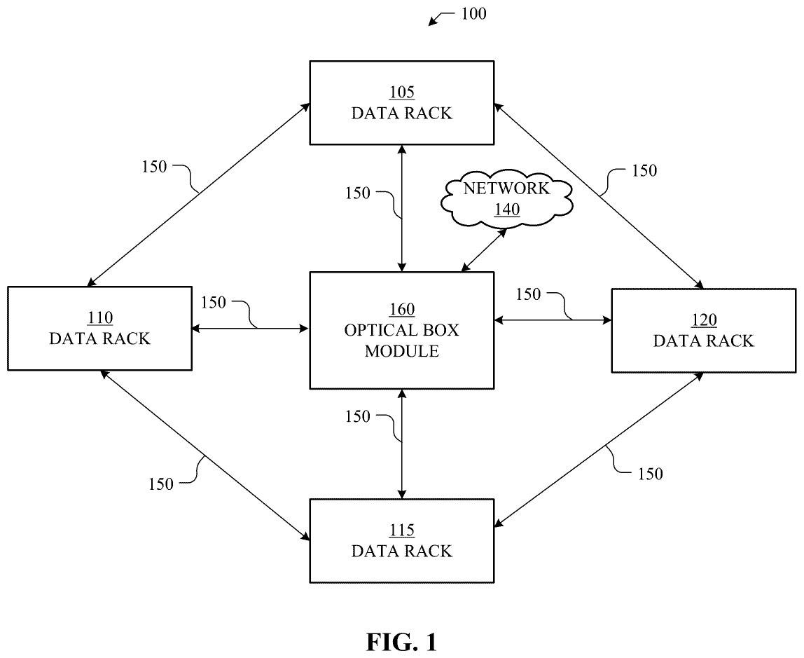

Reference is now made to FIG. 1, which is a block diagram of a system according to exemplary embodiments. As shown in FIG. 1, the system 100 may include one or more data racks 105, 110, 115 and 120 and a centralized hub 160 (also referred to herein as optical box module 160). The system 100 may be maintained by a data center. Additionally, the system 100 may include any suitable network such as, for example, network 140. As an example and not by way of limitation, one or more portions of network 140 may include an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, or a combination of two or more of these. Network 140 may include one or more networks 140. In an exemplary embodiment, the network 140 may facilitate network connectivity between the optical box module 160 and the one or more data racks 105, 110, 115 and 120 (also referred to herein as 4-post data equipment racks (4-PDER) 105, 110, 115 and 120).

Links 150 may connect the data racks 105, 110, 115 and 120 to the optical box module 160 and/or the data racks 105, 110, 115, 120 to each other. In some exemplary embodiments, the one or more links 150 may include fiber strands (e.g., fiber cable, optical cable, etc.) such as, for example, high strand count trunks configured to connect the data racks 105, 110, 115 and 120 to the optical box module 160.

In some exemplary embodiments, the data racks 105, 110, 115, 120 may be electronic devices including hardware, software, and/or embedded logic components or a combination of two or more such components and capable of carrying out the appropriate functionalities implemented or supported by the data racks 105, 110, 115, 120. In some exemplary embodiments, the one or more data racks 105, 110, 115, 120 may each include one or more minipacks (e.g., 12 minipacks such as, for example, 128×100 G (gigabits per second (also referred to herein as Gbps)) ethernet switches, with each minipack including one or more duplex ports (e.g., 128 LC (Lucent Connector) duplex ports). Each of the one or more data racks 105, 110, 115, 120 may be pre-patched to a Multi-Fiber Termination Push-On connector(s) (MTP) adapter panel(s) at the top of each of the one or more data racks 105, 110, 115, 120. The MTP adapter panels at the top of each of the one or more data racks 105, 110, 115, 120 may be utilized to connect the data racks 105, 110, 115, 120 to the optical box module 160.

The optical box module 160 may handle all, or a portion of, fiber striping, fiber shuffling and/or patching logic for the data racks of the system 100 and may facilitate connection between each of the data racks 105, 110, 115, 120 and/or other electronic devices associated with the system 100. In some exemplary embodiments, fiber striping may be a manner to connect fibers to a network device and/or a passive panel in order to achieve a desired signal path with proper polarity. Additionally, in some exemplary embodiments, fiber shuffling may be a manner to arrange fiber inside of a multi-fiber structured cable and/or enclosure to achieve a desired signal path with proper polarity. The MTP adapter panels at the top of each of the one or more data racks 105, 110, 115, 120, described above, may be utilized to connect the data racks 105, 110, 115, 120 to the optical box module 160 via fiber strands (e.g., fiber cable, optical cable, etc.) such as, for example, high strand count trunks. In an instance in which additional data racks may be needed by a data center, the additional data racks may be connected to the optical box module 160 which may port/connect applicable fiber strands between these additional data racks and the optical box module 160.

It should be pointed out that although FIG. 1 shows one optical box module 160 and four data racks 105, 110, 115 and 120 any suitable number of optical box modules 160 and data racks 105, 110, 115 and 120 may be part of the system of FIG. 1 without departing from the spirit and scope of the present disclosure.

### Exemplary Centralized Hub

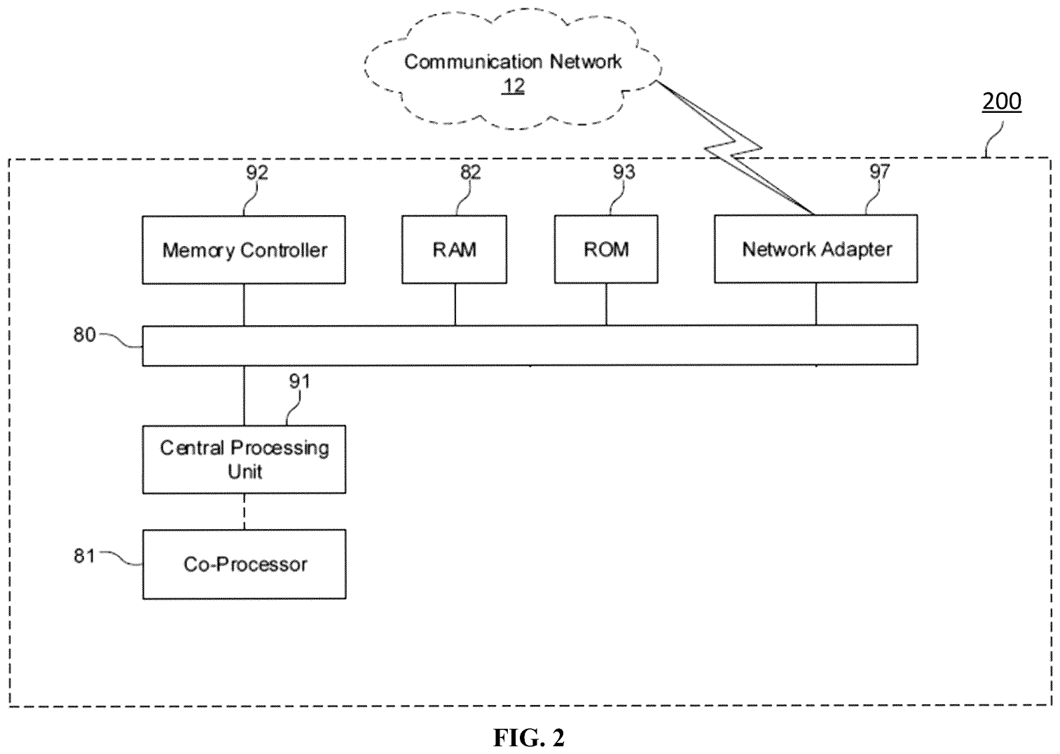

FIG. 2 is a block diagram of an exemplary centralized hub 200. In some exemplary embodiments, the centralized hub 200 (also referred to herein as optical box module 200) may be a centralized hub 160. The centralized hub 200 may comprise a hardware component and may be controlled primarily by computer readable instructions, which may be in the form of software, wherever, or by whatever means such software is stored or accessed. Such computer readable instructions may be executed within a processor, such as central processing unit (CPU) 91, to cause centralized hub 200 to operate. In many exemplary embodiments central processing unit 91 may be implemented by a single-chip CPU called a microprocessor. In other machines, the central processing unit 91 may comprise multiple processors. Coprocessor 81 may be an optional processor, distinct from main CPU 91, that performs additional functions or assists CPU 91.

In operation, CPU 91 fetches, decodes, and executes instructions, and transfers information to and from other resources via the computer's main data-transfer path, system bus 80. Such a system bus connects the components in centralized hub 200 and defines the medium for data exchange. System bus 80 typically includes data lines for sending data, address lines for sending addresses, and control lines for sending interrupts and for operating the system bus. An example of such a system bus 80 is the Peripheral Component Interconnect (PCI) bus.

Memories coupled to system bus 80 include RAM 82 and ROM 93. Such memories may include circuitry that allows information to be stored and retrieved. ROMs 93 generally contain stored data that cannot easily be modified. Data stored in RAM 82 may be read or changed by CPU 91 or other hardware devices. Access to RAM 82 and/or ROM 93 may be controlled by memory controller 92. Memory controller 92 may provide an address translation function that translates virtual addresses into physical addresses as instructions are executed. Memory controller 92 may also provide a memory protection function that isolates processes within the system and isolates system processes from user processes. Thus, a program running in a first mode may access only memory mapped by its own process virtual address space; it cannot access memory within another process's virtual address space unless memory sharing between the processes has been set up.

Further, centralized hub 200 may contain communication circuitry, such as for example a network adaptor 97, that may be used to connect centralized hub 200 to an external communications network, such as network 12, to enable the centralized hub 200 to communicate with other nodes (e.g., data racks 105, 110, 115, 120 and/or other centralized hubs 200) of the network. In some exemplary embodiments, the centralized hub 200 may be embodied within an application-specific integrated circuit (ASIC), a chip or the like.

The centralized hub 200 may handle all, or a portion of, fiber striping and/or patching logic for the data racks (e.g., data racks 105, 110, 115, 120) of a network (e.g., system 100) and may facilitate connection between each of the data racks and/or other electronic devices associated with the network. In some exemplary embodiments, the patching logic may be implemented by the CPU 91 and/or co-processor 81. The centralized hub 200 may facilitate connection of fiber strands (e.g., fiber cable, optical cable, etc.) such as, for example, high strand count trunks between MTP adapter panels of the data racks of a network to facilitate connection to the data racks. The centralized hub 200 may include micro electro-mechanical systems (MEMS), The MEMs of the centralized hub 200 may utilize switches to change an angle(s) of mirrors on plates of the MEMs to reroute fiber strands to connect to other fiber strands.

In an instance in which additional data racks may be needed by a data center, the additional data racks may be connected to the centralized hub 200 which may port/connect applicable fiber strands between these additional data racks and the centralized hub 200. Additionally, the centralized hub 200 may be configured to connect to other centralized hubs 200. In some exemplary embodiments, one or more internal ports of the centralized hub 200 may be equal to the total ports in the data racks (e.g., data racks 300) dedicated to the centralized hub 200.

### Exemplary System Operation

The exemplary embodiments may relate to a mechanism for reducing onsite data center cable patching by having data racks with pre-integrated fiber patching and associated network equipment, and/or one or more reconfigurable optical shuffle box modules (e.g., a centralized hub(s)).

The data racks associated with a data center may connect to a centralized hub. The centralized hub may handle all, or a portion of, the fiber/cable shuffling and/or patching logic for the data racks associated with the data center. In an instance in which additional data racks may be required, these additional data racks may be plugged into the centralized hub, which may port/connect the applicable strands of fiber (e.g., cable) as needed, either using active and/or passive mechanisms.

### Exemplary Data Rack

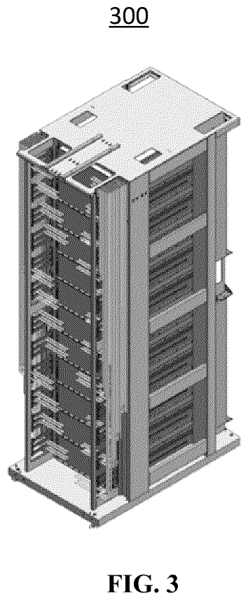

Referring to FIG. 3, a diagram illustrating an exemplary data rack 300 according to an exemplary embodiment is provided. The data rack 300 (also referred to herein as 4-post data equipment rack (4-PDER) 300) may be an example of the data racks 105, 110, 115, 120.

The data rack 300 of the exemplary embodiments may facilitate reduction of onsite data center cable patching based in part on the data rack 300 being a pre-integrated rack with fiber patching and network equipment. The data rack 300 being a pre-integrated rack with fiber patching and network equipment may minimize time intensive network patching from data center builds. The data rack 300 may include device optics, fiber patching and network equipment (e.g., network switches, power distribution units (PDUs), etc.) integrated into the data rack 300. In some example embodiments, the device optics, fiber patching and network equipment may be integrated into the data rack 300 offsite of a data center and may be tested prior to the arrival to the data center. In other example embodiments, the device optics, fiber patching and network equipment may be integrated into the data rack 300 at the data center and may be tested at the data center.

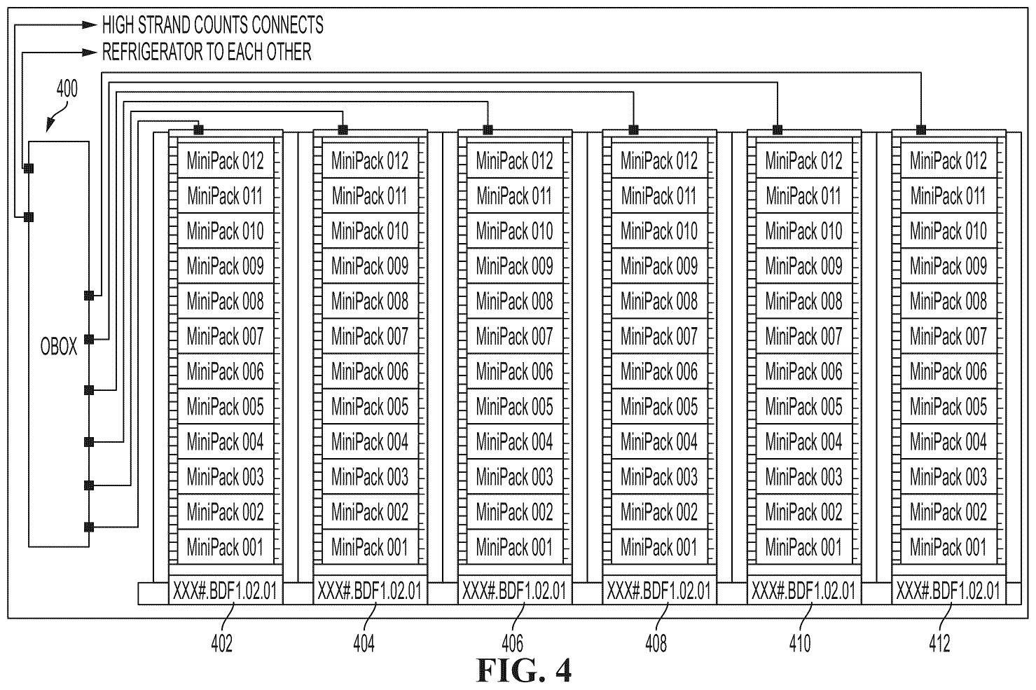

Referring now to FIG. 4, a diagram illustrating an optical box module 400 having internal ports connected to data racks according to an exemplary embodiment is provided. The optical box module (also referred to herein as OBOX) 400 may be an example of the centralized hub 200. The data racks 402, 404, 406, 408, 410, 412 may examples of a data rack 300. The data racks 402, 404, 406, 408, 410, 412 may also be referred to herein as 4-PDERs 402, 404, 406, 408, 410, 412. The 4-PDERs 402, 404, 406, 408, 410, 412 may include minipacks (e.g., 128×100 G ethernet switches). In the example of FIG. 4, the 4-PDERs 402, 404, 406, 408, 410, 412 may include 12 minipacks. However, in other exemplary embodiments, the 4-PDERs 402, 404, 406, 408, 410, 412 may include any suitable number of minipacks.

The OBOX 400 may connect each of the 4-PDERs 402, 404, 406, 408, 410, 412 to the OBOX 400 utilizing fiber strand bundles. Each of the 4-PDERs 402, 404, 406, 408, 410, 412 may be pre-patched to MTP adapter panels at the top of the 4-PDER and these MTP panels may connect to the fiber strand bundles. For purposes of illustration and not of limitation, each of the 4-PDERs 402, 404, 406, 408, 410, 412 may connect to the OBOX 400 using 3,072 F (fiber) OS2 (single mode fiber properties) fiber strand bundles. As such, in this example, the internal ports of the OBOX 400 may be 3,072 F OS2 multiplied by the number of dedicated 4-PDERs 402, 404, 406, 408, 410, 412 which is 6 in this example embodiment. In some other exemplary embodiments, each of the 4-PDERs 402, 404, 406, 408, 410, 412 may connect to the OBOX 400 using any other suitable number of fiber strand bundles. By enabling the OBOX 400 to connect to the dedicated 4-PDERs 402, 404, 406, 408, 410, 412 in this manner, the exemplary embodiments may facilitate reduction of onsite data center patching by having 4-PDERs 402, 404, 406, 408, 410, 412 with pre-integrated fiber patching and enabling the OBOX 400 to facilitate patching logic and handling fiber shuffling among the dedicated 4-PDERs 402, 404, 406, 408, 410, 412.

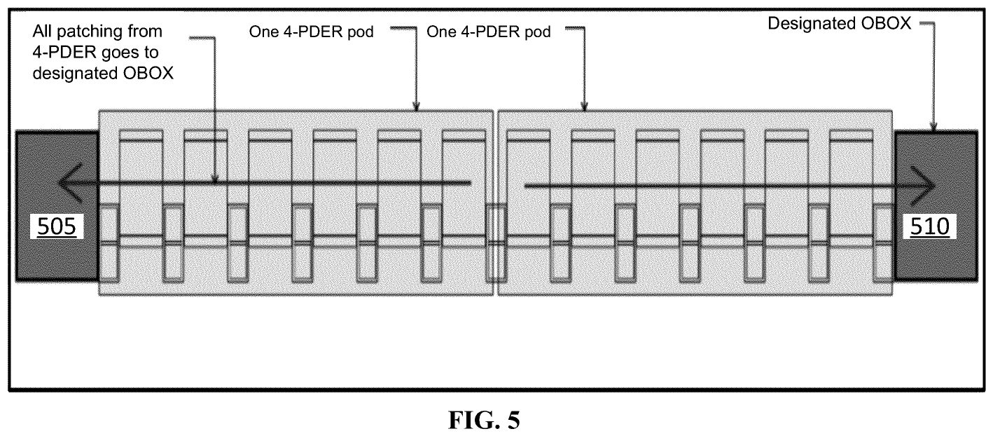

Referring now to FIG. 5, a diagram illustrating multiple optical box modules configured to connect to dedicated racks according to an exemplary embodiment is provided. As shown in FIG. 5, all patching from one dedicated 4-PDER pod may go to one OBOX 505. Additionally, all patching from another dedicated 4-PDER pod may go to another OBOX 510. The two OBOXes of FIG. 5 are configured to connect to their dedicated racks (e.g., via internal ports) and/or to other OBOXes (e.g., via external ports).

In some exemplary embodiments, there may be two OBOX configurations. In the first configuration (e.g., Configuration 1) there may be 4-PDERs grouped by each row. In this regard, an OBOX may be at the end of each row that supports the 4-PDERs in that row. For purposes of illustration and not of limitation, there may be one OBOX per group of 6 4-PDERs (See e.g., FIG. 4). However, other numbers of 4-PDERs per OBOX group are possible (e.g., 7 4-PDERs, 8 4-PDERs, 9 4-PDERs, etc.).

In the second configuration (e.g., Configuration 2) there may be one OBOX per post (e.g., per room) of a data center. In some example embodiments, a post may refer to 1 of 4 physically redundant cabling pathways within a data center(s). In Configuration 2, an OBOX in a proximity (e.g., one OBOX per room or other area) may serve all the 4-PDERs allocated to that post.

Utilizing Configuration 1 and Configuration 2 may drastically reduce the amount of hours required to install fiber/cable by reducing the required onsite cabling pulls and patching. In Configuration 1, the hours associated with cable patching may be reduced from a standard data center configuration of over 100,000 hours to approximately 44,000 hours for Configuration 1. In Configuration 2, the hours associated with cable patching may be reduced from a standard data center configuration of over 100,000 hours to approximately 12,000 hours for Configuration 2.

### ALTERNATIVE EMBODIMENTS

The foregoing description of the embodiments has been presented for the purpose of illustration; it is not intended to be exhaustive or to limit the patent rights to the precise forms disclosed. Persons skilled in the relevant art can appreciate that many modifications and variations are possible in light of the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments also may relate to an apparatus for performing the operations herein. This apparatus may be specially constructed for the required purposes, and/or it may comprise a computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments also may relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed:

1. A system comprising:
a device comprising one or more processors; and
at least one memory storing instructions, that when executed by the one or more processors, cause the device to:
facilitate connection, via a plurality of fiber strands, to ports associated with a first plurality of racks associated with a data center, wherein the plurality of racks comprise pre-integrated fiber patching and associated network equipment; and
facilitate shuffling of fiber between the device and the first plurality of racks.

2. The system of claim 1, wherein when the one or more processors further execute the instructions, the device is configured to:
connect to another device coupled to a second plurality of racks associated with the data center.

3. The system of claim 1, wherein a number of a plurality of internal ports of the device are a multiple of a number of the plurality of racks.

4. The system of claim 1, wherein the device comprises an optical box module.

5. The system of claim 1, wherein the first plurality of racks comprises a plurality of switches having duplex ports.
